(19) United States
(12) Patent Application Publication
(10) Pub. No.: US 2009/0128219 A1
(43) Pub. Date: May 21, 2009

(54) SEMICONDUCTOR DEVICE, POWER SUPPLY DEVICE, AND INFORMATION PROCESSING DEVICE

(75) Inventor: Kiyotaka Umemoto, Kyoto (JP)

Correspondence Address: FISH & RICHARDSON P.C., P.O. BOX 1022, MINNEAPOLIS, MN, 55440-1022, US

(73) Assignee: Rohm Co., Ltd., Kyoto (JP)

(21) Appl. No.: 11/917,185

(22) PCT Filed: Jun. 16, 2006
(86) PCT No.: PCT/JP2006/312167

§ 371 Date: Dec. 11, 2007

(30) Foreign Application Priority Data
Jun. 17, 2005 (JP) 2005-177417

(51) Int. Cl. H03K 17/687; H01L 29/772

(52) U.S. Cl. 327/434; 257/368; 257/369; 257/E29.242

(57) ABSTRACT

A semiconductor device (100) includes a MOS transistor (10) having a back gate region “a”, a first region “b” serving as one of a source region and a drain region, and a second region “c” serving as the other of the source region and the drain region. The semiconductor device further includes an input terminal (20) connected to the first region “b” and to which an input voltage is applied from outside the semiconductor device (100), an output terminal (30) connected to the second region “c” and outputting an output voltage outside the semiconductor device (100), and a back gate control circuit (40) for applying the input voltage or the output voltage to the back gate region “a”. With this configuration of the semiconductor device having the output MOS transistor, even when a reverse bias is applied between the input and the output terminal, the terminals are insulated from each other and lowering of the drain current by the substrate bias effect can be suppressed.

### TECHNICAL FIELD

The present invention relates to a semiconductor device that uses a MOS transistor as an output device.

### BACKGROUND ART

As shown in FIG. 9, a conventional power supply device outputs a desired output voltage via an output terminal 30 by turning the gate of an output MOS transistor 900 on and off. Here, a body diode BD is generally present as a parasitic device between the source region and drain region of the output MOS transistor 900. Thus, if a reverse bias is applied between an input terminal 20 and the output terminal 30 for some cause, a current flows between the source and drain through the body diode BD, and this makes it impossible to insulate between the source region and drain region.

One method for overcoming the above problem resulting from the presence of the body diode BD is disclosed in Patent Document 1 listed below. This method, however, requires a plurality of switches, and hence requires a large circuit area. Moreover, this method uses MOS transistors connected in series, and thus suffers from a high on-state resistance across the MOS transistor in the steady-output state, resulting in low efficiency.

Another method is, as shown in FIG. 10, to connect the backgate of a MOS transistor 910 to a reference potential so that no body diode BD is formed. This makes it possible to insulate between the source region and drain region.

When the configuration shown in FIG. 10 is adopted, the MOS transistor 910 is operated in the unsaturated region. Thus, the drain current Id of the MOS transistor 910 is given by equation (1) below (unsaturated region equation). In equation (1), the parameter Vgs represents the gate-source voltage of the MOS transistor 910, and the parameter Vds represents the drain-source voltage of the MOS transistor 910.

$$\begin{matrix}[ Equation 1 ] & \\ Id = 2 K \cdot ( Vgs - Vt - \frac{Vds}{2} ) \cdot Vds & ( 1 )\end{matrix}$$

The parameter K in equation (1) is given by equation (2) below. In equation (2), the parameter W represents the channel width of the MOS transistor, the parameter L represents the channel length of the MOS transistor, the parameter ∈si represents the dielectric constant of silicon, the parameter tox represents the thickness of the gate oxide film, and the parameter μ represents the carrier mobility in the channel.

$$\begin{matrix}[ Equation 2 ] & \\ K = \frac{W}{L} \cdot \frac{ɛ si}{tox} \cdot μ & ( 2 )\end{matrix}$$

The device threshold voltage Vt in equation (1) is given by equation (3) below. In equation (3), the parameter Vt0 represents the device threshold voltage determined by the process used, the parameters γ and Φf are factors determined by the process, and the parameter Vbsu represents the backgate-source potential difference.

[Equation 3]

Vt=Vt0+γ·(\sqrt{2φf+Vbs}−\sqrt{2φf}) (3)

Patent Document 1: JP-A-H10-341141

Patent Document 2: JP-A-S62-030421

### DISCLOSURE OF THE INVENTION

### Problems to be Solved by the Invention

Certainly, adopting the configuration shown in FIG. 10 helps eliminate the body diode, and thus helps insulate between the source region and drain region of the MOS transistor 910.

However, fixing the backgate region of the MOS transistor 910 at, for example, the ground potential as shown in FIG. 10 produces, as a result of the so-called substrate bias effect, a positive potential difference Vbs between the source region and backgate region of the MOS transistor 910. Thus, compared with when the substrate bias effect is absent (Vbs=0), the device threshold voltage Vt of the MOS transistor 910 given by equation (3) is higher, and hence the drain current Id given by equation (1) is accordingly smaller. Thus, the conventional configuration shown in FIG. 10 suffers from low performance of the MOS transistor 910.

One method for alleviating the substrate bias effect is disclosed in Patent Document 2 listed above. With this method, however, if a reverse bias is applied, a current flows through a parasitic diode, possibly causing an excessive current to flow through the MOS transistor.

An object of the present invention is to provide a semiconductor device that includes a MOS transistor as an output device but that can nevertheless insulate between an input terminal and an output terminal even if a reverse bias is applied between them and that in addition can alleviate the lowering of a drain current resulting from the substrate bias effect.

### Means for Solving the Problem

To achieve the above object, according to one aspect of the invention, a semiconductor device including a MOS transistor having a backgate region, a first region serving as one of a source region and a drain region, and a second region serving as the other of a source region and a drain region may be provided with: an input voltage terminal connected to the first region and receiving an input voltage from outside the semiconductor device; an output voltage terminal connected to the second region and outputting an output voltage to outside the semiconductor device; and a backgate control circuit selecting between the input voltage and the output voltage and feeding one of the input voltage and the output voltage to the backgate region. (A first configuration.)

More specifically, according to this aspect of the invention, a semiconductor device including an N-channel MOS transistor having a backgate region, a first region serving as a source region and a drain region, and a second region serving as the other of a source region and a drain region may be provided with: an input voltage terminal connected to the first region and receiving an input voltage from outside the semiconductor device; an output voltage terminal connected to the second region and outputting an output voltage to outside the semiconductor device; and a backgate control circuit selecting between the input voltage and the output voltage and feeding whichever is lower of the input voltage and the output voltage to the backgate region. (A second configuration.)

Alternatively, according to the above aspect of the invention, a semiconductor device including a P-channel MOS transistor having a backgate region, a first region serving as a source region and a drain region, and a second region serving as the other of a source region and a drain region may be provided with: an input voltage terminal connected to the first region and receiving an input voltage from outside the semiconductor device; an output voltage terminal connected to the second region and outputting an output voltage to outside the semiconductor device; and a backgate control circuit selecting between the input voltage and the output voltage and feeding whichever is higher of the input voltage and the output voltage to the backgate region. (A third configuration.)

According to another aspect of the invention, a semiconductor device is provided with: a MOS transistor having a semiconductor substrate of a first conductivity type, a first second-conductivity-type region of a second conductivity type formed on the semiconductor substrate, a first first-conductivity-type region of the first conductivity type formed within the first second-conductivity-type region, a second second-conductivity-type region of the second conductivity formed within the first first-conductivity-type region and serving as one of a source region and a drain region, a third second-conductivity-type region of the second conductivity type formed within the first first-conductivity-type region and serving as the other of a source region and a drain region, and a second first-conductivity-type region of the first conductivity type formed within the first first-conductivity-type region; and an input voltage terminal connected to the second second-conductivity-type region and receiving an input voltage from outside the semiconductor device; an output voltage terminal connected to the third second-conductivity-type region and outputting an output voltage to outside the semiconductor device; and a backgate control circuit applying one of the input voltage and the output voltage to the second first-conductivity-type region. (A fourth configuration.)

In the semiconductor device of the fourth configuration described above, preferably, the first conductivity type is P-type conductivity, the second conductivity type is N-type conductivity, and the backgate control circuit applies whichever is lower of the input voltage and the output voltage to the backgate region. (A fifth configuration.)

Alternatively, in the semiconductor device of the fourth configuration described above, preferably, the first conductivity type is N-type conductivity, the second conductivity type is P-type conductivity, and the backgate control circuit applies whichever is higher of the input voltage and the output voltage to the backgate region. (A sixth configuration.)

According to another aspect of the invention, a semiconductor device including a MOS transistor having a backgate region, a first region serving as one of a source region and a drain region, and a second region serving as the other of a source region and a drain region is provided with: an input voltage terminal connected to the first region and receiving an input voltage from outside the semiconductor device; an output voltage terminal connected to the second region and outputting an output voltage to outside the semiconductor device; and a backgate control circuit applying a voltage to the backgate region such that a voltage applied to the source region and the voltage applied to the backgate region are equal. (A seventh configuration.)

In the semiconductor device of any one of the first to seventh configurations, preferably, there is further provided: a gate control circuit controlling a voltage applied to the gate of the MOS transistor such that the output voltage remains constant. (An eighth configuration.)

According to another aspect of the invention, a semiconductor device including a MOS transistor having a backgate region, a first region serving as one of a source region and a drain region, and a second region serving as the other of a source region and a drain region, the semiconductor device comprising: an input voltage terminal connected to the first region and receiving an input voltage from outside the semiconductor device; an output voltage terminal connected to the second region and outputting an output voltage to outside the semiconductor device; a comparator inverting an output thereof according to the voltage relationship between the input voltage and the output voltage; a first switch opened and closed according to the output of the comparator, a first end of the first switch being connected to the input voltage terminal, a second end of the first switch being connected to the backgate region of the MOS transistor; a second switch opened and closed complementarily with the first switch according to the output of the comparator, a first end of the second switch being connected to the output voltage terminal, a second end of the second switch being connected to the backgate region of the MOS transistor; and controlling means for controlling the gate terminal of the MOS transistor, the controlling means having a low-voltage output terminal at which the controlling means outputs a minimum gate voltage so that the backgate region is connected to a terminal at which a lower voltage appears. (A ninth configuration.)

According to yet another aspect of the invention, a power supply device is provided with: the semiconductor device of the eighth or ninth configuration described above; an inductive element of which one end is connected to an output terminal of the semiconductor device; and a capacitive element of which one end is connected to the other end of the inductive element and of which the other end is connected to a node to which a reference voltage is applied. (A tenth configuration.)

According to still another aspect of the invention, an information processing device is provided with: the semiconductor device of the eighth or ninth configuration described above; an alternating-current-to-direct-current conversion device connected to an input terminal of the semiconductor device; a secondary battery connected to an output terminal of the semiconductor device; and controlling means supplied with electric power from the alternating-current-to-direct-current conversion device and from the secondary battery.

### ADVANTAGES OF THE INVENTION

According to the invention, it is possible to prevent a parasitic diode from acting as such, without increasing the potential difference between a backgate region and a source region or between a backgate region and a drain region; hence, it is possible to insulate between an input terminal and an output terminal.

In other words, according to the invention, it is possible to prevent a reverse current from an output terminal to an input terminal, and in addition to apply to a backgate region a voltage equal to that applied to a source region or a drain region. Thus, it is possible to reduce the potential difference between the backgate region and the source region, and hence it is possible to alleviate a lowering of the drain current Id. That is, according to the invention, it is possible to save a MOS transistor from poor operation.

Moreover, according to the invention, there is no need to provide a plurality of MOS transistors in series; thus, it is possible to avoid an increase in circuit area or in output on-state resistance.

As discussed above, according to the invention, in a semiconductor device including a MOS transistor as an output device, by controlling the backgate region of the MOS transistor according to the voltage at its source or drain region, more specifically, by selecting a voltage equal to the voltage at the drain or source region of the MOS transistor and applying the so selected voltage to the backgate region of the MOS transistor, it is possible, even when a reverse bias is applied between an input terminal and an output terminal, to insulate between the two terminals. In addition, in the steady-output state, it is possible to reduce the lowering of the drain current Id resulting from the substrate bias effect. Thus, the previously stated object of the invention is fulfilled.

In short, according to the invention, it is possible to achieve insulation between an input terminal and an output terminal without lowering the performance of a MOS transistor.

### BRIEF DESCRIPTION OF DRAWINGS

FIG. 1 A diagram showing, as a first embodiment, a power supply device employing a semiconductor device according to the invention.

FIG. 2 A circuit diagram showing the details of the backgate control circuit 40.

FIG. 3 A diagram showing the cross-sectional structure of the MOS transistor 10 and its interconnection with the backgate control circuit 40 etc.

FIG. 4 A diagram showing the interconnection between the MOS transistor 11, having a different cross-sectional structure from that shown in FIG. 3, and the backgate control circuit 40 etc.

FIG. 5 A circuit diagram of a step-down power supply device employing a semiconductor device according to the invention.

FIG. 6 A diagram showing, as a second embodiment, a power supply device employing a semiconductor device according to the invention.

FIG. 7 A diagram showing the configuration of an information processing device employing a semiconductor device according to the invention.

FIG. 8 A diagram showing the electrical interconnection around the information processing device 7000.

FIG. 9 A circuit diagram showing an example of a conventional power supply device.

FIG. 10 A circuit diagram showing another example of a conventional power supply device.

### LIST OF REFERENCE SYMBOLS

10, 11 MOS transistors
20 Input Terminal
30 Output Terminal
40 Backgate Control Circuit
41 Comparator
100, 110 Semiconductor Device
200 Control Circuit (Gate Control Circuit)
210 Comparator
300 Inductive Element
400 Capacitive Element
500 Load
1000 Semiconductor Device
7000 Information Processing Device
710 AC-DC Conversion Device
720 Secondary battery
730 Controlling Means (Mother Board)
760 Control Circuit
SW1, SW2 Switches
inv1 Inverter
VL Low-Voltage Output Terminal

### BEST MODE FOR CARRYING OUT THE INVENTION

To begin with, a first embodiment of the invention will be described.

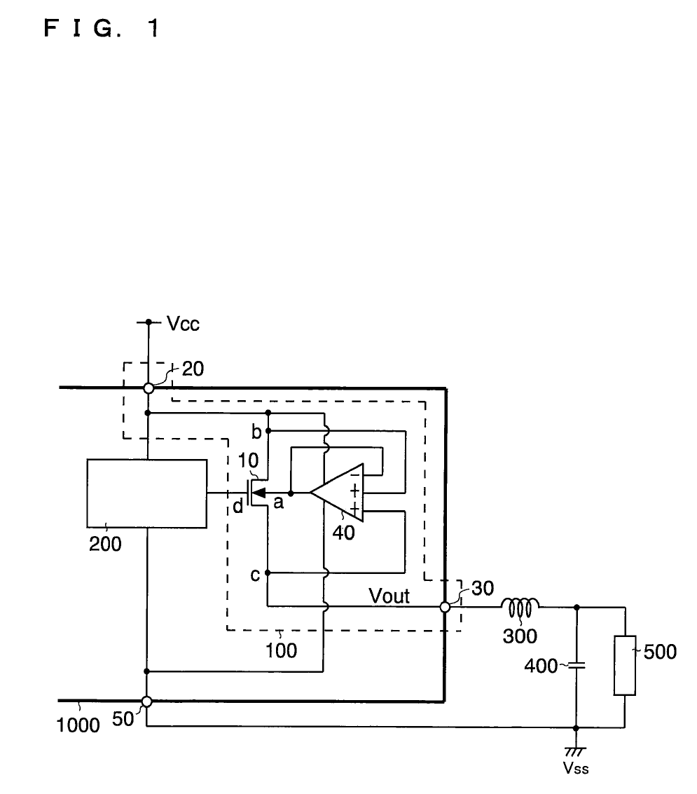

FIG. 1 is a diagram showing, as a first embodiment, a power supply device employing a semiconductor device according to the invention.

As shown in FIG. 1, the semiconductor device 100 of this embodiment forms part of a semiconductor device 1000. The semiconductor device 100 is composed of: a MOS transistor 10 having a backgate terminal “a”, a first region “b” serving as one of a source region and a drain region, and a second region “c” serving as the other of a source region and a drain region; an input terminal 20 that is connected to the first region “b” and to which, for example, a supply voltage Vcc is applied as an input voltage from outside the semiconductor device 1000; an output terminal 30 that is connected to the second region “c” and from which an output voltage Vout is outputted to outside the semiconductor device 1000; and a backgate control circuit 40 that applies either the input voltage Vcc or the output voltage Vout to the backgate terminal “a”.

The control terminal “d” of the MOS transistor 10 is connected to a control circuit 200. The control circuit 200 is, for example, so configured as to control the MOS transistor 10 based on the output voltage Vout so that the output voltage Vout remains constant, or so configured as to control the MOS transistor 10 based on the current flowing through an inductive element 300 so that the output current remains constant. The control circuit 200 may control the MOS transistor 10 based on the current flowing through a load 500. Here, it should be noted that the control circuit 200 controls the MOS transistor 10 independently of the backgate control circuit 40.

The output voltage Vout outputted from the output terminal 30 is smoothed by the inductive element 300 and a capacitive element 400, and is then outputted to the load 500.

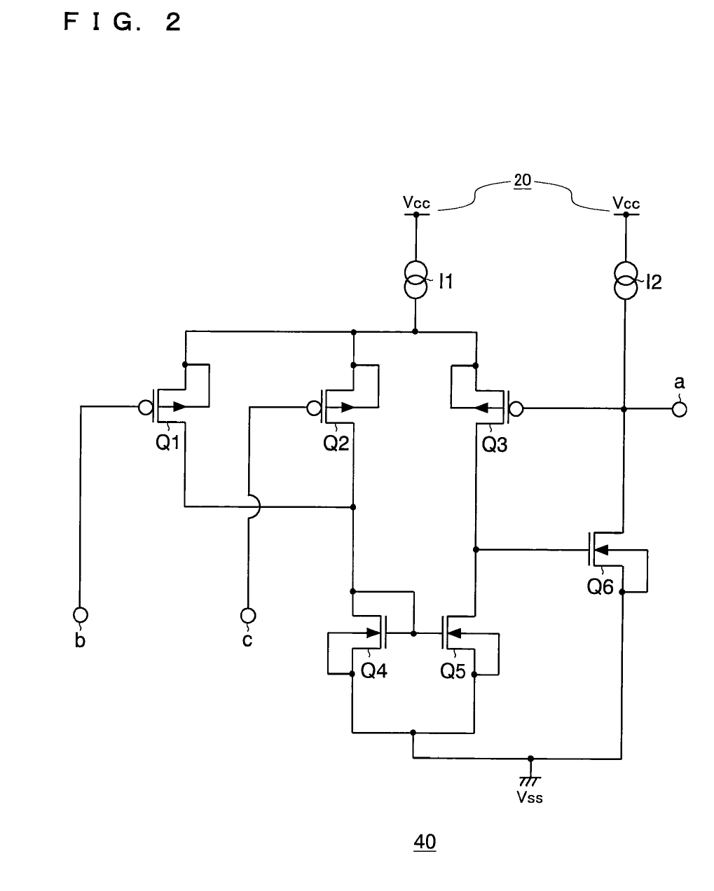

FIG. 2 is a circuit diagram showing the details of the backgate control circuit 40.

As shown in FIG. 2, the backgate control circuit 40, for example, includes a differential operation portion composed of: a first constant current source I1 of which a first end is connected to the input terminal 20; a P-channel MOS transistor Q1 of which the source region is connected to a second end of the first constant current source I1 and of which the gate terminal is connected to the first region “b” of the MOS transistor 10; a P-channel MOS transistor Q2 of which the source region is connected to the second end of the first constant current source I1 and of which the gate terminal is connected to the second region “c” of the MOS transistor 10; and a P-channel MOS transistor Q3 of which the source region is connected to the second end of the first constant current source I1 and of which the gate terminal is connected to the backgate terminal “a” of the MOS transistor 10.

The backgate control circuit 40 further includes a current mirror circuit composed of: an N-channel MOS transistor Q4 of which the drain region is connected to the drain regions of the transistors Q1 and Q2 and of which the source region is connected to a node to which a reference voltage Vss is applied, with the gate terminal of the transistor Q4 connected to its own drain region; and an N-channel MOS transistor Q5 of which the drain region is connected to the drain region of the transistor Q3 and of which the source region is connected to the node to which the reference voltage Vss is applied, with the gate terminal of the transistor Q5 connected to the gate terminal of the transistor Q4.

The backgate control circuit 40 further includes a feedback control portion composed of: a second constant current source 12 of which a first end is connected to the input terminal 20; the transistor Q5 mentioned above, and an N-channel MOS transistor Q6 of which the gate terminal is connected to the drain region of the transistor Q3 and of which the drain region is connected to the backgate terminal “a” of the MOS transistor 10 and to a second end of the second constant current source 12, with the source region of the transistor Q6 connected to the node to which the reference voltage Vss is applied.

Here, the P-channel MOS transistors Q1, Q2, and Q3 are the same size, and the N-channel MOS transistors Q4, Q5, and Q6 are the same size.

To alleviate the substrate bias effect, the backgate regions of these MOS transistors Q1 to Q6 are connected to their respective source or drain regions as appropriate as shown in FIG. 2.

Now the operation of the backgate control circuit 40 configured as described above will be described. Consider a case where the supply voltage Vcc is 2 V and the reference voltage Vss is 0 V, and suppose now that, for example, a voltage of 2 V is applied to the second region “c” and a voltage of 1 V is applied to the first region “b”. In this condition, since the voltage applied to the second region “c” equals the supply voltage Vcc, the gate-source voltage of the P-channel MOS transistor Q2 equals 0 V. Thus, the P-channel MOS transistor Q2 is in a cutoff state (off state). On the other hand, since a voltage of 1 V is applied between the gate and source of the P-channel MOS transistor Q1, a drain current commensurate with that voltage flows through the N-channel MOS transistor Q4. Moreover, since the N-channel MOS transistors Q4 and Q5 form a current mirror circuit, a mirror current commensurate with the current flowing through the N-channel MOS transistor Q4 flows through the N-channel MOS transistor Q5.

Moreover, since equal currents flow through the P-channel MOS transistor Q3 and the N-channel MOS transistor Q5, a voltage similar to that applied to the first region “b” appears at the gate terminal of the P-channel MOS transistor Q1. Thus, whichever is lower of the voltages applied to the first and second regions “b” and “c” (in the condition currently being discussed, the voltage applied to the first region “b”) is applied to the backgate terminal “a”.

The only difference in a condition where the voltage applied to the second region “c” is lower than that applied to the first region “b” is that the P-channel MOS transistors Q1 and Q2 switch their states with each other. In a condition where the voltages applied to the first and second regions “b” and “c” are close together, drain currents flow through both the P-channel MOS transistors Q1 and Q2, and a difference arises between the voltage applied to these regions “b” and “c” and that applied to the backgate terminal “a”. This, however, poses no problem in practicing the invention, allowing it to offer the effects shown in FIG. 1.

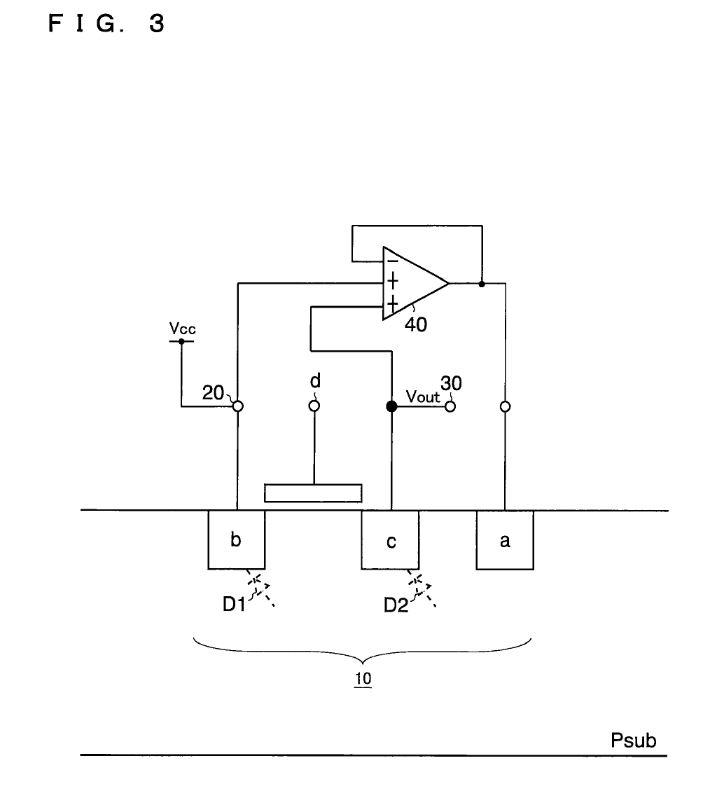

Next, with reference to FIG. 3, the operation of the semiconductor device 100 will be described.

FIG. 3 shows the cross-sectional structure of the MOS transistor 10 and its interconnection with the backgate control circuit 40 etc.

For example, the first region “b” of the MOS transistor 10 is connected to the input terminal 20, to which the supply voltage Vcc is applied; and the second region “c” of the MOS transistor 10 is connected to the output terminal 30, from which the output voltage Vout is outputted.

First, a case will be dealt with in which the supply voltage Vcc is higher than the output voltage Vout. In this condition, the backgate terminal “a” for applying a voltage to the backgate region of the MOS transistor 10 (i.e., a P-type substrate Psub) receives from the backgate control circuit 40 a voltage equal to the output voltage Vout. Accordingly, the second region “c” and the backgate terminal “a” have equal potentials, and thus the backgate-source potential difference represented by Vbs in equation (3) noted earlier equals zero, allowing a sufficient drain current.

Next, a case will be dealt with in which the supply voltage Vcc is lower than the output voltage Vout, a condition called a reverse-biased condition. In this condition, the backgate terminal “a” receives from the backgate control circuit 40 a voltage equal to the supply voltage Vcc. Accordingly, the parasitic diode D2 present between the P-type substrate Psub and the second region “c” is reverse-biased, and thus no current flows through the P-type substrate Psub between the second region “c” and the first region “b”, achieving insulation between the drain region and the source region.

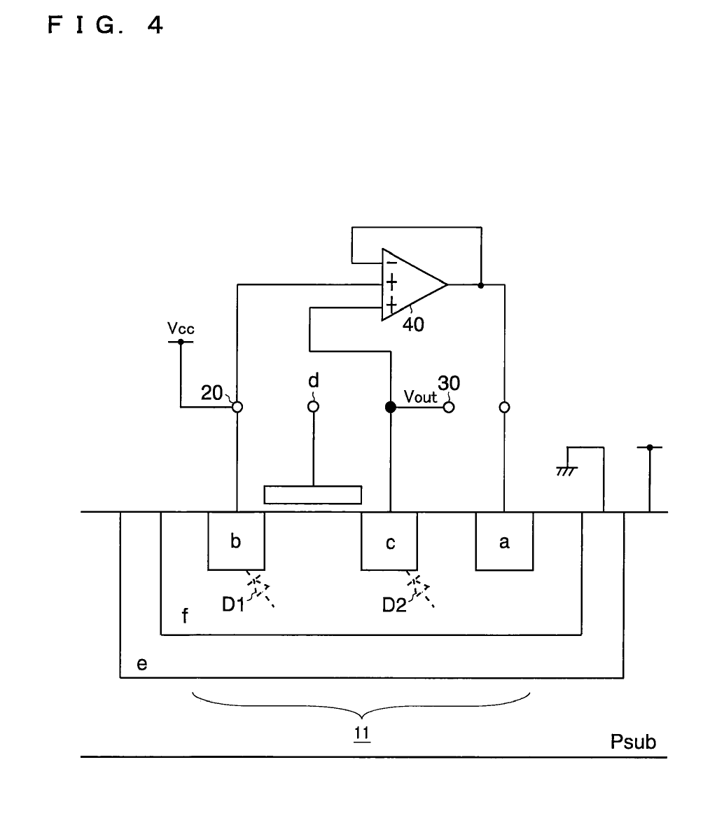

Instead, a MOS transistor 11 having a structure as shown in FIG. 4 may be used as the output transistor. The MOS transistor 11 shown in FIG. 4 has, formed on a semiconductor substrate Psub of P-type conductivity to which a supply voltage Vcc is applied: a first N-type conductivity region “e” of N-type conductivity to which a reference voltage Vss is applied; a first P-type conductivity region “f” of P-type conductivity formed within the first N-type conductivity region “e”; a second N-type conductivity region “b” of N-type conductivity (corresponding to the first region “b” in FIG. 3, and thus hereinafter called the first region “b”) formed within the first P-type conductivity region “f” and serving as one of a source region or a drain region; a third N-type conductivity region “c” of N-type conductivity (corresponding to the second region “c” in FIG. 3, and thus hereinafter called the second region “c”) formed within the first P-type conductivity region “f” and serving as the other of a source region or a drain region; and a second P-type conductivity region “a” of P-type conductivity (corresponding to the backgate terminal “a” in FIG. 3, and thus hereinafter called the backgate terminal “a”) formed within the first P-type conductivity region “f”.

That is, the MOS transistor 11 shown in FIG. 4 has, formed on the semiconductor substrate Psub of P-type conductivity, the first N-type conductivity region “e”, and has, formed within the first N-type conductivity region “e”, the first P-type conductivity region “f”. And, here, the MOS transistor 10 is formed within the first P-type conductivity region “f”, and in this respect, the structure here differs from that shown in FIG. 3.

Now the operation of the MOS transistor 11 shown in FIG. 4 will be described.

For example, the first region “b” of the MOS transistor 11 is connected to the input terminal 20, to which the supply voltage Vcc is applied; and the second region “c” of the MOS transistor 11 is connected to the output terminal 30, from which the output voltage Vout is outputted.

First, a case will be dealt with in which the supply voltage Vcc is higher than the output voltage Vout. In this condition, the backgate terminal “a” for applying a voltage to the backgate region of the MOS transistor 10 (i.e., the first P-type conductivity region “f”) receives from the backgate control circuit 40 a voltage equal to the output voltage Vout. Accordingly, the second region “c” and the backgate terminal “a” have equal potentials, and thus the backgate-source potential difference represented by Vbs in equation (3) noted earlier equals zero, allowing a sufficient drain current.

Next, a case will be dealt with in which the supply voltage Vcc is lower than the output voltage Vout, a condition called a reverse-biased condition. In this condition, the backgate terminal “a” receives from the backgate control circuit 40 a voltage equal to the supply voltage Vcc. Accordingly, the parasitic diode D2 present between the first P-type conductivity region “f” and the second region “c” is reverse-biased, and thus no current flows through the first P-type conductivity region “f” between the second region “c” and the first region “b”, achieving insulation between the drain region and the source region.

When the MOS transistor 11 structured as shown in FIG. 4 is used as the output transistor in the invention, the backgate terminal “a” of the MOS transistor 11 receives the output voltage from the backgate control circuit 40 without being affected by the noise applied to the semiconductor substrate Psub. Thus, compared with a MOS transistor having no first P-type conductivity region “f” (i.e., having the structure as shown in FIG. 3), it is possible to more effectively reduce the likeliness of the parasitic diode present in the MOS transistor 11 acting as such; that is, it is possible to insulate between the input terminal 20 and the output terminal 30.

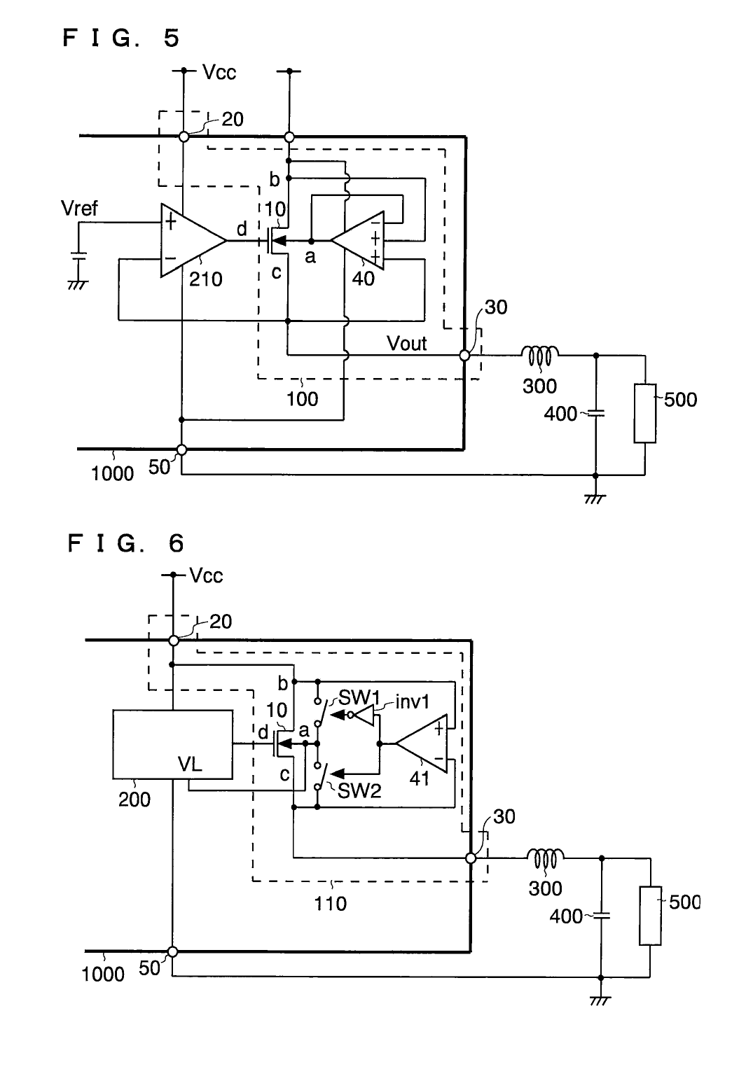

FIG. 5 is a circuit diagram of a step-down power supply device (step-down switching regulator) employing a semiconductor device according to the invention.

In the step-down power supply device shown in FIG. 5, in place of the control circuit 200 in FIG. 1, a comparator 210 is used. This comparator 210 has its inverting input terminal (−) connected to the output terminal 30, and has its non-inverting input terminal (+) connected to a node to which a reference voltage Vref is applied. Thus, according to the comparison output from the comparator 210, the gate terminal “d” of the MOS transistor 10, serving as the output transistor, is controlled.

Next, a second embodiment of the invention will be described.

FIG. 6 is a diagram showing, as a second embodiment, a power supply device employing a semiconductor device according to the invention.

As shown in FIG. 6, the semiconductor device 110 of this embodiment is composed of: a comparator 41 of which the non-inverting input terminal (+) is connected to the input terminal 20 and of which the inverting input terminal (−) is connected to the output terminal 30; an inverter circuit inv1 that receives the output of the comparator 41; a first switch SW1 that is opened and closed according to the output of the inverter circuit inv1, with a first end of the first switch SW1 connected to the input terminal 20 and a second end of the first switch SW1 connected to the backgate terminal “a” of the MOS transistor 10; and a second switch SW2 that is opened and closed according to the output of the comparator 41, with a first end of the second switch SW2 connected to the output terminal 30 and a second end of the second switch SW2 connected to the backgate terminal “a” of the MOS transistor 10.

Thus, the backgate terminal “a” of the MOS transistor 10 receives whichever is lower of the input voltage (supply voltage Vcc) and the output voltage Vout.

Switching of the MOS transistor 10 is controlled by a control circuit 200 that pulsates the gate voltage of the MOS transistor 10 between high and low levels, and the backgate terminal “a” of the MOS transistor 10 is also connected to a low-voltage output terminal VL of the control circuit 200 (at which it outputs the minimum gate voltage).

Now the operation of the semiconductor device 110 configured as described above will be described. When the output voltage Vout is lower than the input voltage (supply voltage Vcc), according to the comparison result from the comparator 41, the second switch SW2 is closed and the first switch SW1 is opened. Here, the backgate terminal “a” of the MOS transistor 10 receives a voltage equal to the output voltage Vout, no potential difference arises between the source region and backgate region of the MOS transistor 10. Thus, it is possible to alleviate the substrate bias effect, allowing the flow of a larger drain current than is conventionally possible.

By contrast, when the input voltage (supply voltage Vcc) is lower than the output voltage Vout, according to the comparison result from the comparator 41, the first switch SW1 is closed and the second switch SW2 is opened. Accordingly, the backgate terminal “a” of the MOS transistor 10 receives the voltage (supply voltage Vcc) applied to the input terminal 20, and thus the parasitic diode in the MOS transistor 10 remains reverse-biased, maintaining drain-source insulation.

Here, the use of the comparator 41 in place of a buffer amplifier for the control of the backgate terminal “a” allows more stable operation than the circuit described previously as the first embodiment.

In addition to the already mentioned effects, the application of the minimum gate voltage of the MOS transistor 10 to the source region “c”, the backgate terminal “a”, and the gate terminal “d” makes it possible to cut off the MOS transistor 10 completely. Thus, it is possible to reduce current leakage and thereby achieve low power consumption, making the invention suitable for use in power supplies for portable appliances operating from batteries.

Next, a third embodiment of the invention will be described.

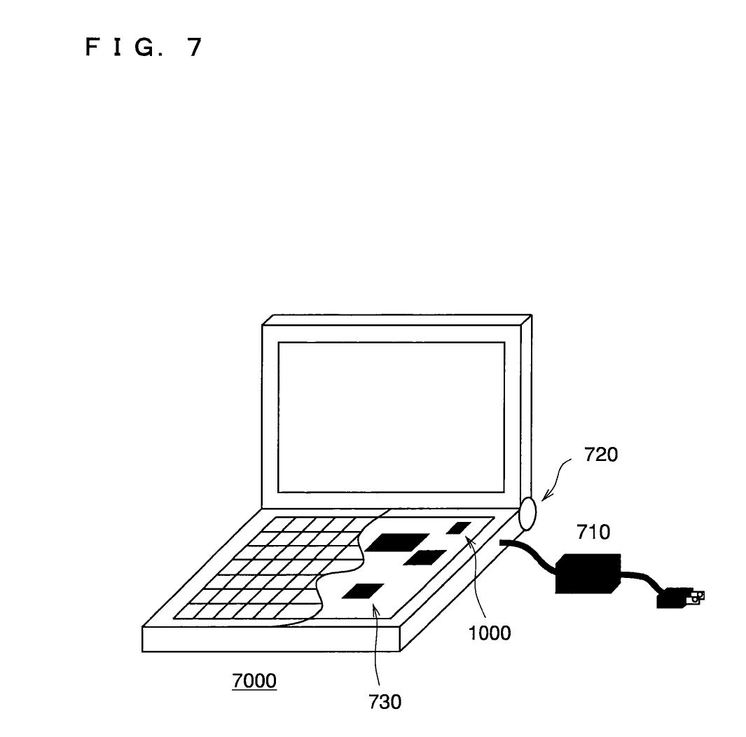

FIG. 7 is a diagram showing the configuration of an information processing device employing a semiconductor device according to the invention.

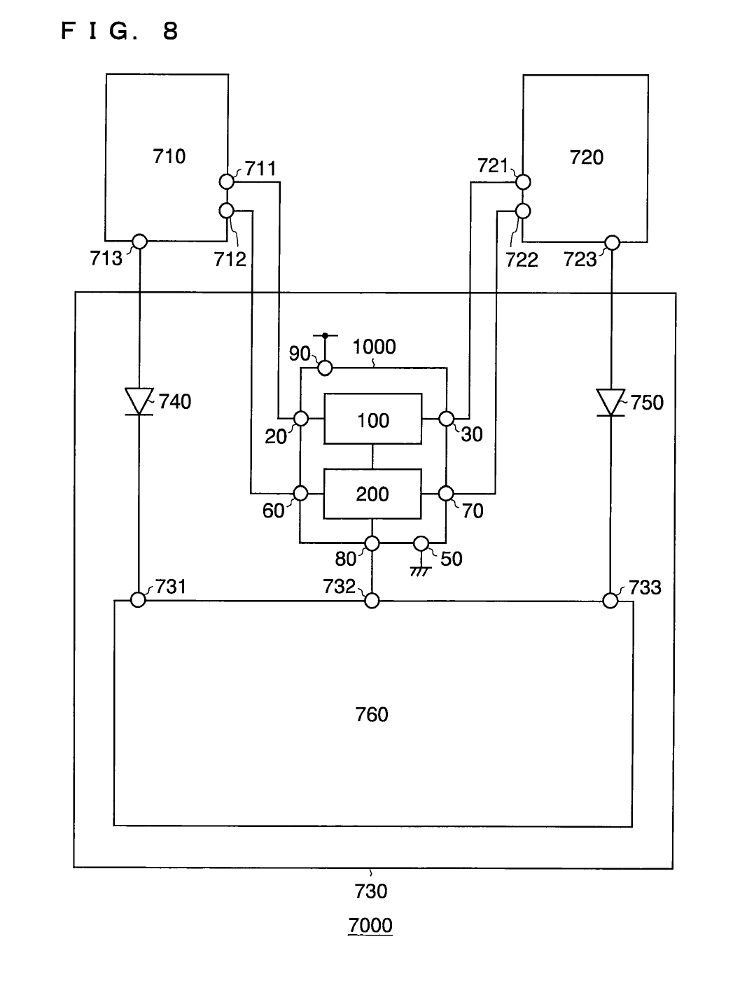

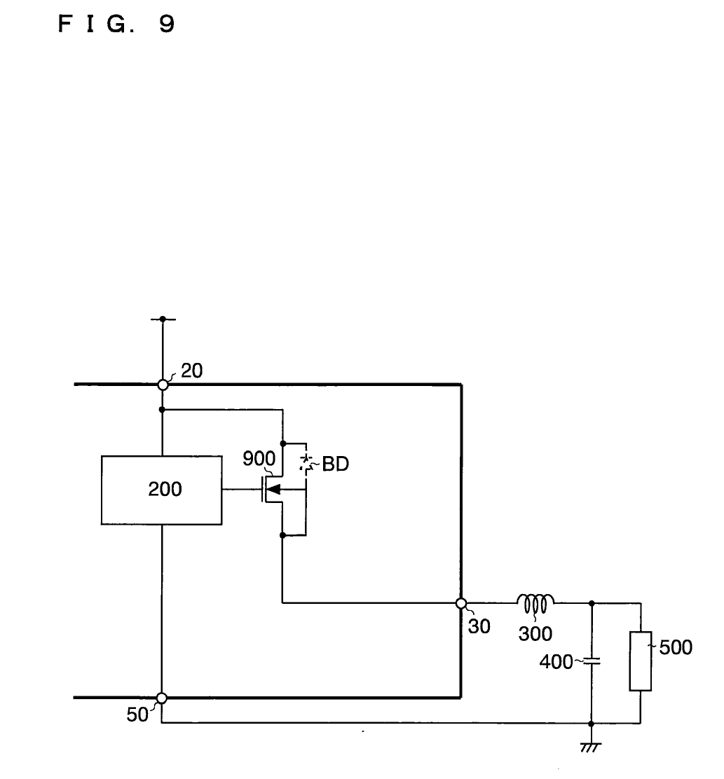

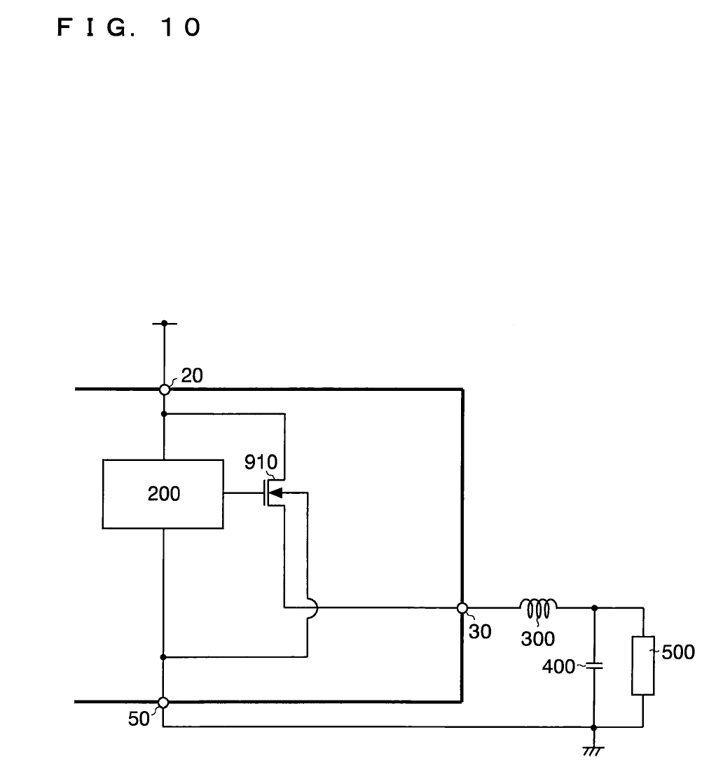

In FIG. 7, the reference numeral 710 represents an AC-DC (alternating current to direct current) conversion device, such as an AC adaptor, for producing a direct-current voltage (for example, 21 V) from alternating-current power distributed to households. The reference numeral 720 represents a secondary battery, that is, a rechargeable battery, using lithium, such as a lithium-polymer battery or a lithium-ion battery. The reference numeral 1000 represents a semiconductor device according to the invention like those previously described. The reference numeral 730 represents means for controlling an information processing device 7000 (such as a notebook personal computer), as typically realized in the form of a mother board 730. On the mother board 730, in addition to the semiconductor device 1000 according to the invention, other control circuits (such as the control circuit 760 shown in FIG. 8 described later) are also mounted.

FIG. 8 is a diagram showing the electrical interconnection around the information processing device 7000.

A control circuit 760 mounted on the mother board 730 operates by being supplied with electric power from the AC-DC conversion device 710 or from the secondary battery 720 via a diode 740 or via a diode 750 respectively. The input terminal 20 of the semiconductor device 1000 is connected to the voltage output terminal 711 of the AC-DC conversion device 710, and the output terminal 30 of the semiconductor device 1000 is connected to the voltage input terminal 721 of the secondary battery 720. Moreover, the semiconductor device 1000 receives, at its signal input terminal 80, a control signal from the control circuit 760 for controlling the control circuit 200.

In a case where the secondary battery 720 alone is connected to the information processing device 7000, a supply voltage is supplied from the secondary battery 720 via the diode 750 to the control circuit 760. In a case where the AC-DC conversion device 710 alone is connected to the information processing device 7000, a supply voltage is supplied from the AC-DC conversion device 710 via the diode 740 to the control circuit 760.

Next, a description will be given of the operation in a case where both the AC-DC conversion device 710 and the secondary battery 720 are connected and the voltage supplied from the AC-DC conversion device 710 is higher than that supplied from the secondary battery 720. In this case, the control circuit 760 monitors the voltage from the secondary battery 720 and, if this voltage is equal to or lower than a predetermined voltage, the control circuit 760 feeds a control signal to the semiconductor device 1000, from a terminal 732 of the former to the terminal 80 of the latter, to instruct the semiconductor device 1000 to turn the gate of its output transistor on so that a current is supplied from the AC-DC conversion device 710 via the semiconductor device 1000 to the secondary battery 720. Thus, the secondary battery 720 is charged. Here, compared with the conventional configuration (where the backgate of the output transistor is simply connected to the reference voltage), the semiconductor device 1000 according to the invention (more particularly, the semiconductor device 100 according to the invention) allows a sufficient drain current to flow, and thus allows the secondary battery 720 to be charged in less time.

The foregoing deals with a case where the control circuit 760 checks whether or not the output voltage of the secondary battery 720 is equal to or lower than a predetermined voltage; alternatively, it is also possible to connect the signal terminal 712 of the AC-DC conversion device 710 to the signal terminal 60 of the semiconductor device 1000 and connect the signal terminal 722 of the secondary battery 720 to the signal terminal 70 of the semiconductor device 1000 so that the semiconductor device 1000 (more particularly, the control circuit 200) makes such a check.

Next, a description will be given of the operation in a case where both the AC-DC conversion device 710 and the secondary battery 720 are connected and the voltage supplied from the AC-DC conversion device 710 is lower than that supplied from the secondary battery 720. This occurs, for example, when, for some cause or other, the output of the AC-DC conversion device 710 fails and suffers a drop in voltage, or when, with no AC-DC conversion device 710 connected, dust collected in the adaptor jack short-circuits the contact there to the reference potential.

In this case, for example, as will now be described in terms of FIG. 3, the semiconductor substrate Psub, which is connected to the backgate terminal “a” of the MOS transistor 10 serving as the output transistor in the semiconductor device 100, receives a voltage (for example, the reference potential) equal to that at the input terminal 20. Accordingly, the parasitic diode D2 present between the semiconductor substrate Psub and the second region “c” is reverse-biased, and thus no current flows through the semiconductor substrate Psub between the second region “c” and the first region “b”, achieving insulation between the drain region and the source region. Through the workings described above, the MOS transistor 10 is protected from overcurrent and hence from breakdown.

The foregoing deals with a case where an N-channel MOS transistor is used as the output transistor; alternatively, it is also possible to use a P-channel MOS transistor, in which case effects similar to those described above can be obtained by outputting as the output voltage of the backgate control circuit 40 whichever is higher of the voltages applied to the first and second regions “b” and “c”.

1. A semiconductor device including a MOS transistor having a backgate region, a first region serving as either a source region or a drain region, and a second region serving as the other of the source region or the drain region, the semiconductor device comprising:
an input voltage terminal connected to the first region to receive an input voltage from outside the semiconductor device;
an output voltage terminal connected to the second region to provide an output voltage to outside the semiconductor device; and
a backgate control circuit to select between the input voltage and the output voltage and to feed either the input voltage or the output voltage to the backgate region.

2. A semiconductor device including an N-channel MOS transistor having a backgate region, a first region serving as either a source region or a drain region, and a second region serving as the other of the source region or the drain region, the semiconductor device comprising:
an input voltage terminal connected to the first region to receive an input voltage from outside the semiconductor device;
an output voltage terminal connected to the second region to provide an output voltage to outside the semiconductor device; and
a backgate control circuit to select between the input voltage and the output voltage and to feed whichever is lower of the input voltage and the output voltage to the backgate region.

3. A semiconductor device including a P-channel MOS transistor having a backgate region, a first region serving as either a source region or a drain region, and a second region serving as the other of the source region or the drain region, the semiconductor device comprising:
an input voltage terminal connected to the first region to receive an input voltage from outside the semiconductor device;
an output voltage terminal connected to the second region to provide an output voltage to outside the semiconductor device; and
a backgate control circuit to select between the input voltage and the output voltage and to feed whichever is higher of the input voltage and the output voltage to the backgate region.

4. A semiconductor device comprising:
a MOS transistor including:
a semiconductor substrate of a first conductivity type,
a first second-conductivity-type region of a second conductivity type on the semiconductor substrate,
a first first-conductivity-type region of the first conductivity type within the first second-conductivity-type region,
a second second-conductivity-type region of the second conductivity within the first first-conductivity-type region and serving as either a source region or a drain region,
a third second-conductivity-type region of the second conductivity type within the first first-conductivity-type region and serving as the other of the source region or the drain region, and
a second first-conductivity-type region of the first conductivity type within the first first-conductivity-type region; and
an input voltage terminal connected to the second second-conductivity-type region to receive an input voltage from outside the semiconductor device;
an output voltage terminal connected to the third second-conductivity-type region to provide an output voltage to outside the semiconductor device; and
a backgate control circuit to apply either the input voltage or the output voltage to the second first-conductivity-type region.

5. The semiconductor device according to claim 4, wherein
the first conductivity type is P-type conductivity,
the second conductivity type is N-type conductivity, and
the backgate control circuit is configured to apply whichever is lower of the input voltage and the output voltage to the backgate region.

6. The semiconductor device according to claim 4, wherein
the first conductivity type is N-type conductivity,
the second conductivity type is P-type conductivity, and
the backgate control circuit is configured to apply whichever is higher of the input voltage and the output voltage to the backgate region.

7. A semiconductor device including a MOS transistor including a backgate region, a first region serving as either a source region or a drain region, and a second region serving as the other of the source region or the drain region, the semiconductor device comprising:
an input voltage terminal connected to the first region to receive an input voltage from outside the semiconductor device;
an output voltage terminal connected to the second region to provide an output voltage to outside the semiconductor device; and
a backgate control circuit to apply a voltage to the backgate region such that a voltage applied to the source region and the voltage applied to the backgate region are equal.

8. The semiconductor device according to claim 1, further comprising:
a gate control circuit to control a voltage applied to a gate of the MOS transistor such that the output voltage remains constant.

9. A semiconductor device including a MOS transistor having a backgate region, a first region serving as either a source region or a drain region, and a second region serving as the other of the source region or the drain region, the semiconductor device comprising:
an input voltage terminal connected to the first region and to receive an input voltage from outside the semiconductor device;
an output voltage terminal connected to the second region to provide an output voltage to outside the semiconductor device;
a comparator to invert an output thereof according to a voltage relationship between the input voltage and the output voltage;
a first switch opened and closed according to the output of the comparator, a first end of the first switch being connected to the input voltage terminal, a second end of the first switch being connected to the backgate region of the MOS transistor;
a second switch opened and closed complementarily with the first switch according to the output of the comparator, a first end of the second switch being connected to the output voltage terminal, a second end of the second switch being connected to the backgate region of the MOS transistor; and
controlling means for controlling a gate terminal of the MOS transistor, the controlling means having a low-voltage output terminal at which the controlling means outputs a minimum gate voltage so that the backgate region is connected to a terminal at which a lower voltage appears.

10. A power supply device comprising:
the semiconductor device according to claim 8 or 9;
an inductive element of which one end is connected to an output terminal of the semiconductor device; and
a capacitive element of which one end is connected to the other end of the inductive element and of which the other end is connected to a node to which a reference voltage is applied.

11. An information processing device comprising:
the semiconductor device according to claim 8 or 9;
an alternating-current-to-direct-current conversion device connected to an input terminal of the semiconductor device;
a secondary battery connected to an output terminal of the semiconductor device; and
controlling means to receive electric power from the alternating-current-to-direct-current conversion device and from the secondary battery.
